(19) United States
(12) Patent Application Publication
(10) Pub. No.: US 2025/0073845 A1
(43) Pub. Date: Mar. 6, 2025

(54) WAFER BACKGRINDING

(71) Applicant: TEXAS INSTRUMENTS INCORPORATED, DALLAS, TX (US)

(72) Inventors: GAIL EDSELLE REYES, ANGELES CITY (PH); CONNIE ESTERON, MABALACAT (PH)

(21) Appl. No.: 18/459,129

(22) Filed: Aug. 31, 2023

(51) Int. Cl. B24B 41/06; B24B 7/22; H01L 21/304; H01L 21/683; H01L 21/78

(52) U.S. Cl. CPC B24B 41/068; B24B 7/228; H01L 21/304; H01L 21/6836; H01L 21/78

(57) ABSTRACT

A device for a grinding table includes a shim with a cross section shaped to mirror a cross section of a step gap formed at an edge of grinding tape adhered to a first side of a wafer that covers solder balls, such that the shim and the grinding tape form a planer surface on a grinding table for the wafer.

### TECHNICAL FIELD

This description relates to backgrinding a wafer for the fabrication of integrated circuit (IC) chips.

### BACKGROUND

Wafer-Level Chip Scale Package (WCSP), is a semiconductor packaging method that achieves compact and highly integrated chip packaging, reducing package dimensions by closely aligning with a size of the chip. This results in shorter electrical connections, and enhances performance in terms of both electrical and thermal properties. WCSP offers cost and space efficiency, making WCSP a favored choice in space-constrained applications such as mobile devices and wearables devices, where achieving excellent performance through efficient integration is preferable.

In contrast to conventional processing technique that involving molding operations, WCSP avoids the use of molding for chip encapsulation. Instead, WCSP employs a redistribution layer (RDL) process to establish connections between a microchip's pads and external solder balls directly on the wafer. This obviates the need for a separate molded plastic or ceramic package to encase the microchip.

Backgrinding, also referred to as backside grinding or wafer thinning, is a semiconductor manufacturing operation that involves reducing a thickness of a silicon wafer after front-side processing. This is achieved through precision grinding of a backside of the wafer using abrasive materials. By making the wafer thinner, benefits such as improved thermal performance, reduced signal delay, and enhanced electrical performance due to shorter interconnect lengths are realized. After grinding, a polishing operation is often employed to ensure uniform thickness. Backgrinding is employed to create thin and lightweight devices like mobile computing devices, contributing to the miniaturization and improved functionality of such devices by allowing for better heat dissipation and smaller form factors.

### SUMMARY

A first example is related to a device for a grinding table. The device includes a shim with a cross section shaped to mirror a cross section of a step gap formed at an edge of grinding tape adhered to a first side of a wafer that covers solder balls, such that the shim and the grinding tape form a planer surface on the grinding table for the wafer.

A second example relates to a method for backgrinding a wafer including seating a device on a grinding table, wherein the device includes a shim for a wafer. The method includes seating grinding tape adhered to a first side of a wafer on the device. The shim has a cross section shaped to mirror a cross section of a step gap formed at an edge of the grinding tape that covers solder balls on the first side of the wafer, such that the shim and the grinding tape form a planer surface on the grinding table. The method also includes backgrinding a second side of the wafer to form a planer surface on the second side of the wafer.

A third example relates to a method for backgrinding a wafer including seating a device on a grinding table, the device includes a shim for a wafer. The method includes seating grinding tape adhered to a first side of a wafer on the device, wherein the grinding tape covers solder balls on the first side of the wafer. The method also includes backgrinding a second side of the wafer to form a planer surface on the second side of the wafer. The backgrinding includes applying pressure on the second side of the wafer. The shim of the device is shaped to curtail bending of the wafer about a solder ball of the solder balls that is closest to an edge of the grinding tape. The method further includes removing a portion of the second side of the wafer to provide a backgrinded wafer, and the backgrinded wafer has a continuous lattice.

### BRIEF DESCRIPTION OF THE DRAWINGS

FIG. 1 illustrates an example device for facilitating backgrinding of a wafer.

FIG. 2 illustrates a zoomed in view of a portion of the wafer illustrated in FIG. 1.

FIG. 3A illustrates a cross-sectional view of the device illustrated in FIG. 1, wherein the wafer is removed from view.

FIG. 3B illustrates an overhead view of the device illustrated in FIG. 1, wherein the wafer is removed from view.

FIG. 4 illustrates a first stage of an example method of forming IC chips from a wafer.

FIG. 5 illustrates a second stage of the example method for forming IC chips from the wafer.

FIG. 6 illustrates a third stage of the example method for forming the IC chips from the wafer.

FIG. 7 illustrates a fourth stage of the example method for forming the IC chips from the wafer.

FIG. 8 illustrates a fifth stage of the example method for forming the IC chips from the wafer.

FIG. 9 illustrates photographs of backgrinded wafers.

FIG. 10 illustrates a set of graphs that plots an undulation of backgrinded wafers as a function of distance from an edge of the backgrinded wafer.

FIG. 11 illustrates a flowchart of an example method for forming IC chips from a wafer.

### DETAILED DESCRIPTION

This description relates to a device designed for facilitating the backgrinding process of wafers used in integrated circuit (IC) chips. The device is mountable on or integrated with a grinding table. The device has a circular or oval shape, and the device can either be integrated with or removable from the grinding table. The device is intended for use with wafers such as Wafer-Level Chip Scale Package (WCSP) wafers, but is also employable with other types of wafers that have edge planarity issues. The wafers have a silicon layer with an embedded circuit layer on a first side. The circuit layer contains circuitry for the IC chips. A set of solder balls is arranged to provide electrical conduction to pads on the circuit layer, and a grinding tape adheres to the first side of the wafer to cover the set of solder balls. The solder balls are positioned near a center of wafer and do not extend to the edges.

The grinding tape has varying thicknesses across the wafer due to the absence of solder balls at the periphery, creating an uneven planarity. To compensate for this varying thickness (referred to as a step gap), the device incorporates a shim that encircles a periphery of the grinding tape. The shim has a shape that mirrors the unevenness caused by the varying thickness of grinding tape, aiming to create a more uniform and planer surface. The grinding tape and the shim work together to form a planer (and level) surface on a vacuum table of the grinding table. This ensures stability during the backgrinding process where downward force (pressure) is applied to a second side of the wafer (opposite the first side) to reduce a thickness of the silicon layer of the wafer. The shim prevents wafer movement (e.g., rocking), maintains even thickness reduction, and prevents cracking, resulting in a backgrinded wafer with consistent thickness and structural integrity. Thus, the device that includes the shim is referred to as a flattening jig in some examples.

Accordingly, the device improves the backgrinding operation of wafers in IC chip production. By using the shim in conjunction with the grinding tape, the device ensures even planarity and stability during the grinding process, resulting in wafers with consistent thickness and structural integrity. Employment of the device does not significantly increase the production steps or costs associated with IC chip manufacturing from the wafers.

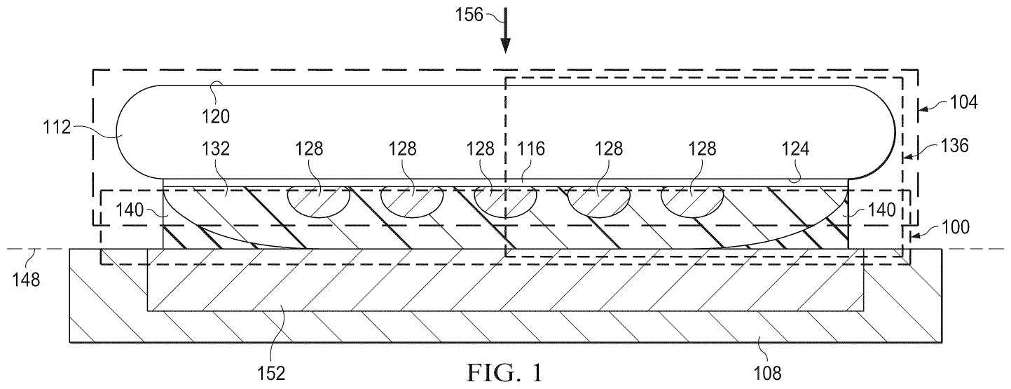

FIG. 1 illustrates a cross-sectional view of a device 100 to facilitate backgrinding of a wafer 104. The device 100 can be mounted on a grinding table 108. The device 100, the grinding table 108 and the wafer 104 have a circular or oval shape in some examples. In some examples, the device 100 is integrated with the grinding table 108. In other examples, the device 100 is removeable from the grinding table 108. In some examples, the wafer 104 is a Wafer-Level Chip Scale Package (WCSP) wafer. In other examples, the wafer 104 is a different type of wafer that commonly experiences edge planarity issues. The wafer 104 includes a silicon layer 112 with a first side 116 and a second side 120 that opposes the first side 116. The first side 116 includes a circuit layer 124 that underlies the first side 116 of the silicon layer 112. The circuit layer 124 includes circuitry embedded in silicon to execute functions for an integrated circuit (IC) chip formed from the wafer 104.

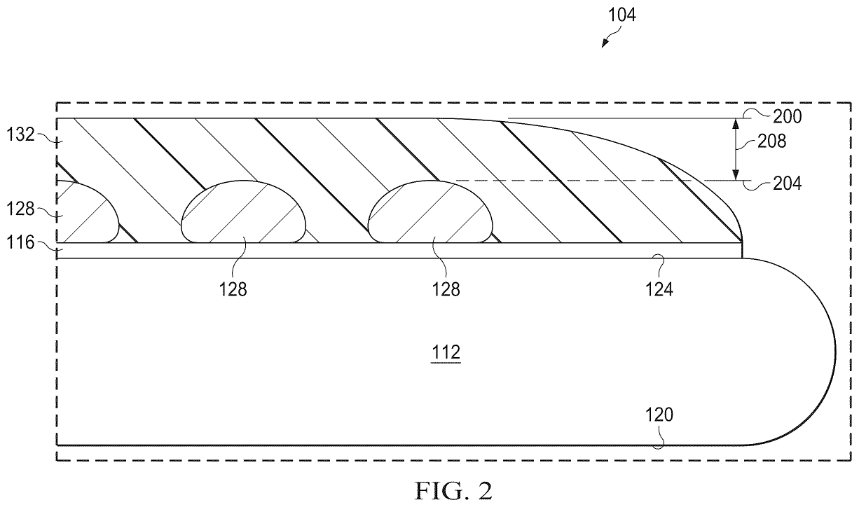

A set of solder balls 128 are formed to contact pads of the circuit layer 124. A grinding tape 132 overlays the set of solder balls 128 and is adhered to the first side 116 of the wafer 104. The set of solder balls 128 are arranged proximate to a center of the wafer 104, and the set of solder balls 128 do not extend to the periphery of the wafer 104. Accordingly, a solder ball 128 of the set of solder balls 128 that is closest to the periphery of the 104 can be about 1 millimeter (mm) to about 3 mm from the periphery of the wafer 104. The grinding tape 132 has a tapered edge near the periphery of the wafer 104 due to the absence of the solder balls 128 in this area. FIG. 2 illustrates this concept. More particularly, FIG. 2 illustrates a zoomed-in view of a region 136 of the wafer 104 of FIG. 1. Thus, FIGS. 1 and 2 employ the same reference numbers to denote the same structure. Additionally, other components have been removed for clarity, and the wafer 104 is shown inverted in FIG. 2.

As illustrated in detail in FIG. 2, a region of the grinding tape 132 that overlays the set of solder balls 128 has a first thickness, and a region of the grinding tape 132 that extends to the periphery of the wafer 104 has a second thickness, smaller than the first thickness (forming the taper). Thus, the grinding tape 132 has an uneven planarity across the wafer 104. A difference in height at a line 200 extending from a portion of the grinding tape 132 at the first thickness (greatest thickness) and a line 204 extending from a top of a solder ball 128 that is closest to the tapered edge of the grinding tape 132 is referred to as a step gap 208. Stated differently, the step gap 208 has a height measured from a point at a greatest thickness of the grinding tape 132 to a point on a solder ball 128 proximate to the edge of the grinding tape 132. The step gap can be, for example, about 40 micrometers (μm) to about 60 μm.

Referring back to FIG. 1, to offset the uneven planarity of the grinding tape 132 (formed by the step gap 208), the device 100 includes a shim 140 that extends around a periphery of the grinding tape 132. As noted, the device 100 has a circular or oval shape, such that FIG. 1 illustrates two (2) portions of the shim 140. The shim 140 is shaped such that a cross-section of the shim 140 mirrors the step gap 208 formed at the tapered edge of the grinding tape 132. That is, the shim 140 is shaped to offset the step gap 208 of the grinding tape 132. In some examples, the shim 140 is referred to as having a gum height to compensate for the step gap 208 of FIG. 2. The grinding tape 132 and the shim 140 operate in concert to form a planer surface 148 on a vacuum table 152 of the grinding table 108. The vacuum table 152 draws in air to apply a downward force in a direction indicated by an arrow 156, keeping the wafer 104 stationary during a grinding operation.

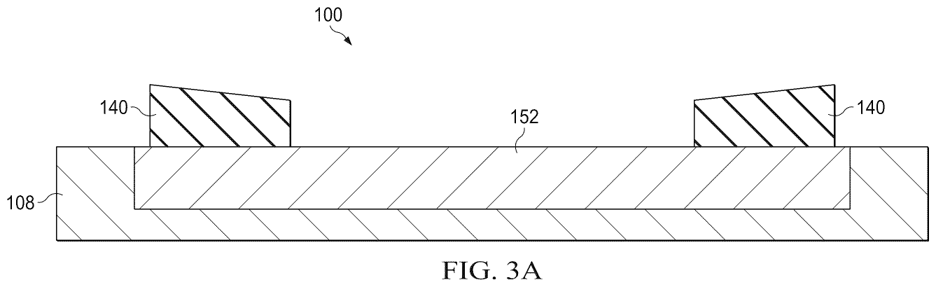

FIGS. 3A and 3B illustrate the device 100 wherein the wafer 104 has been removed. More particularly, FIG. 3A illustrates a cross-sectional view of the device 100 (similar to FIG. 1) and FIG. 3B illustrates an overhead view of the device 100. Thus, FIGS. 1, 3A and 3B employ the same reference numbers to denote the same structure. As illustrated in FIG. 3B, the shim 140 has a circular shape that is situated on the vacuum table 152 of the grinding table 108. The shape of the shim 140 enables the wafer 104 (not shown in FIGS. 3A and 3B) to be seated on the device 100 in a manner illustrated in FIG. 1.

Referring back to FIG. 1, as noted, the shim 140 is shaped to ensure that the grinding tape 132 and the shim 140 form the planer surface 148 on the vacuum table 152 of the grinding table 108. During a backgrinding process, a downward force (e.g., pressure) in a direction indicated by the arrow 156 is applied to the second side 120 of the silicon layer 112. The backgrinding operation removes layers of the silicon layer 112 to reduce an overall thickness of the silicon layer 112. Moreover, the shim 140 cooperates with the grinding tape 132 to provide the planer surface 148, preventing rocking, bending and/or braking of wafer 104 during the backgrinding process. In this manner, the device 100 operates as a flattening jig. Thus, the shim 140 holds the wafer 104 in place (stationary) during the backgrinding operation to ensure that the silicon layer 112 has a thickness that varies (e.g., undulation) by 5 um or less over a full surface of the silicon layer 112 after the backgrinding is executed. Moreover, the shim 140 prevents cracking during the backgrinding operation, such that the resultant wafer 104 has a continuous lattice. Moreover, inclusion of the device 100 does not increase the process steps and/or cost for forming IC chips from the wafer 104.

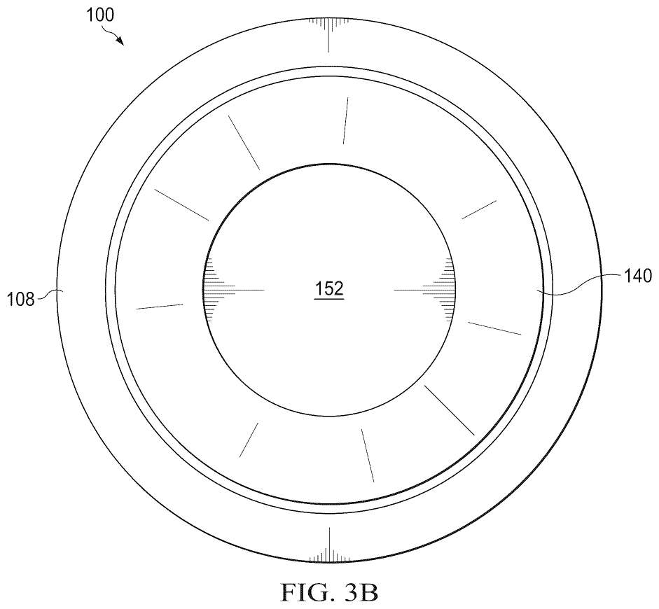

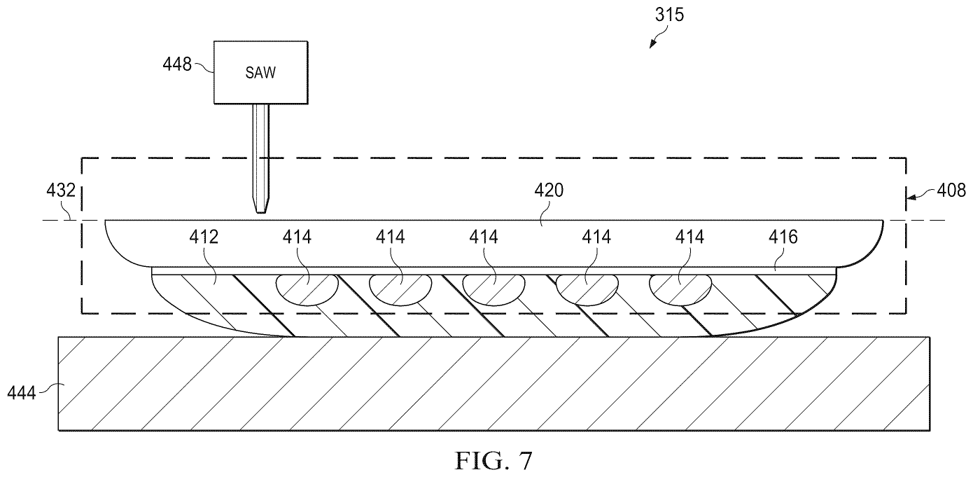

FIGS. 4-8 illustrate stages of a method of forming IC chips from a WCSP wafer. For simplicity, FIGS. 4-8 employ the same reference numbers to denote the same structure.

At 300, in a first stage of the method, as illustrated in FIG. 4, a device 400 (e.g., the device 100 of FIG. 1) is seated on a grinding table 404 (e.g., the grinding table 108 of FIG. 1). The device 400 includes a shim 402 for receiving a wafer 408 (e.g., a WCSP wafer). The grinding table 404 includes a vacuum table 406. In some examples, the shim 402 is held in place by suction formed by the vacuum table 406.

Also at 300, grinding tape 412 adhered to a first side 416 the wafer 408 is seated on the shim 402. More specifically the grinding tape is adhered to an underside of a silicon layer 420 of the wafer 408. The grinding tape 412 covers a set of solder balls 414 that are formed on the first side 416 of the wafer 408. The solder balls 414 have a solder ball 414 that is closest to an edge of the grinding tape 412. The shim 402 is shaped such that a cross section of a step gap (e.g., the step gap 208 of FIG. 1) formed at an edge of the grinding tape 412 is mirrored by the shim 402. To seat the grinding tape 412 on the shim 402, the wafer 408 is moved toward the device 400 in a direction indicated by an arrow 418.

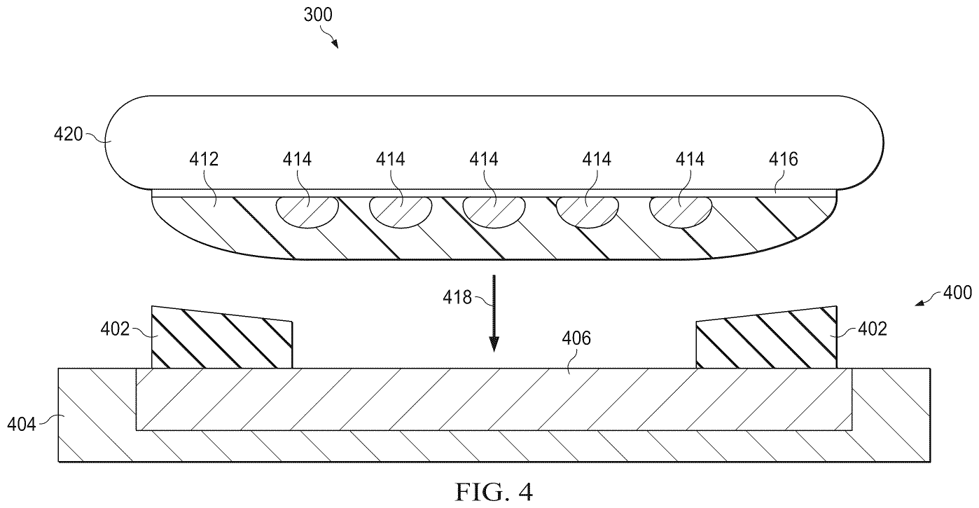

At 305, in a second stage of the method, as illustrated in FIG. 5, the wafer 408 is seated in the device 100 such that a planer surface 424 is formed on the vacuum table 406. Also, at 305, a backgrinding operation of the wafer 408 is initiated. In the backgrinding operation, a portion of the silicon layer 420 of the wafer 408 is removed. In the backgrinding operation, a portion of a second side 428 of the wafer 408 is removed, and the second side 428 is distal from the set of solder balls 414. More particularly, in the example illustrated, during the backgrinding operation the portion of the silicon layer 420 above a marked line 432 is removed.

In various examples, different materials are employable to execute the backgrinding operation at 305. The selection of materials for the backgrinding operation depends on several factors, including wafer type, desired thickness reduction and manufacturing tools. Materials employed for the backgrinding operation encompass diamond grinding wheels to curtail damage to the wafer 408. Additionally, in some examples, complementary grinding fluids and/or coolants are employed to lubricate and/or cool the process to prevent overheating and potential cracks. In some examples, polishing pads with fine abrasives are applied to achieve a smoother surface of the wafer 408 after the backgrinding. Moreover, protective coatings may be applied to shield the wafer's backside during the backgrinding. In some examples, chemical mechanical planarization (CMP) slurries are utilized for further thinning and polishing, blending chemical reactions with mechanical abrasion. During the backgrinding operation a downward force (pressure) is applied in a direction indicated by an arrow 436. The shim 402 of the device 400 is shaped to curtail bending of the wafer 408 about a solder ball 414 of the set of solder balls 414 that is closest to an edge of the grinding tape 412. The planer surface 424 formed on the vacuum table 406 curtails rocking of the wafer 408 during the grinding operation. The backgrinding operation can include, for example, multiple passes to reduce a thickness of the silicon layer 420 to a desired level. The backgrinding of the wafer 408 removes a portion of the second side of the wafer 408 to provide a backgrinded wafer.

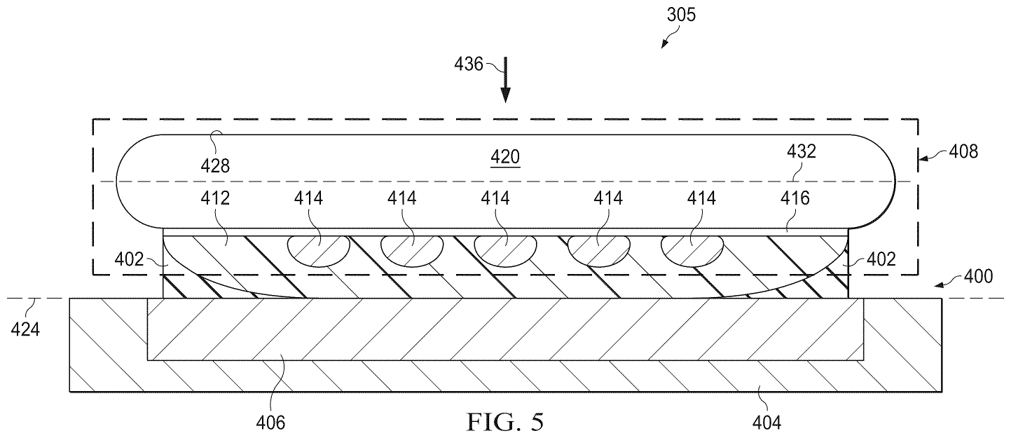

At 310, in a third stage of the method, as illustrated in FIG. 6, the wafer 408 is removed from the grinding table 404. The resultant silicon layer 420 has a surface variance of about 5 μm or less. Moreover, the wafer 408 has a continuous lattice (e.g., no cracks) as a result of the backgrinding operation. As illustrated in FIG. 6, the wafer 408 is backgrinded (at 305), such that the marked line 432 is a top of the silicon layer 420 of the wafer 408. To remove the wafer 408 from the grinding table 404, the wafer 408 is lifted in a direction indicated by an arrow 440. The wafer 408 can be moved to a dicing table.

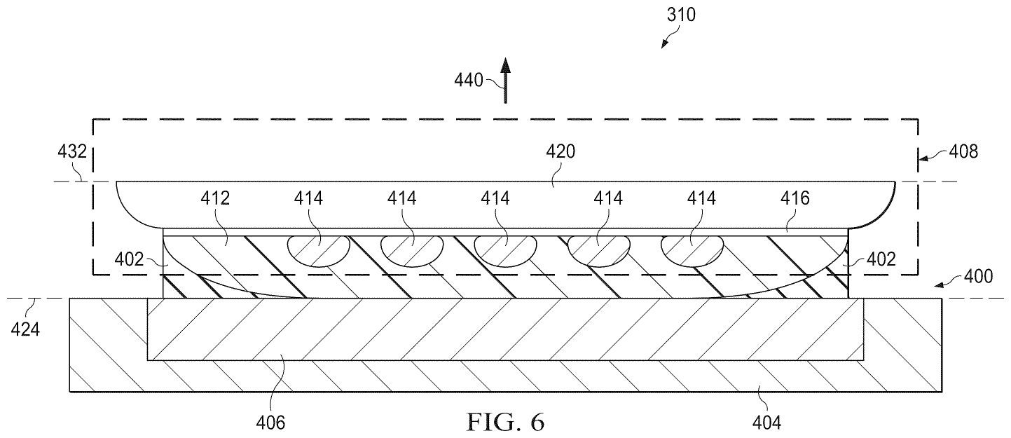

At 315, in a fourth stage of the method, as illustrated in FIG. 7, the wafer 408 is seated on the dicing table 444. Also at 315, dies of the wafer 408 are singulated with a saw 448. The saw 448 could be, for example, a laser saw or a plasma saw. The resultant singulated dies are removed from the dicing table 444.

At 320, the grinding tape 412 is removed from the singulated dies prior to mounting a singulated die 450 on a printed circuit board (PCB). Removal of the grinding tape 412 exposes the set of solder balls 414 of the singulated die 450 to enable an electrical connection to circuit components embedded in the singulated die 450.

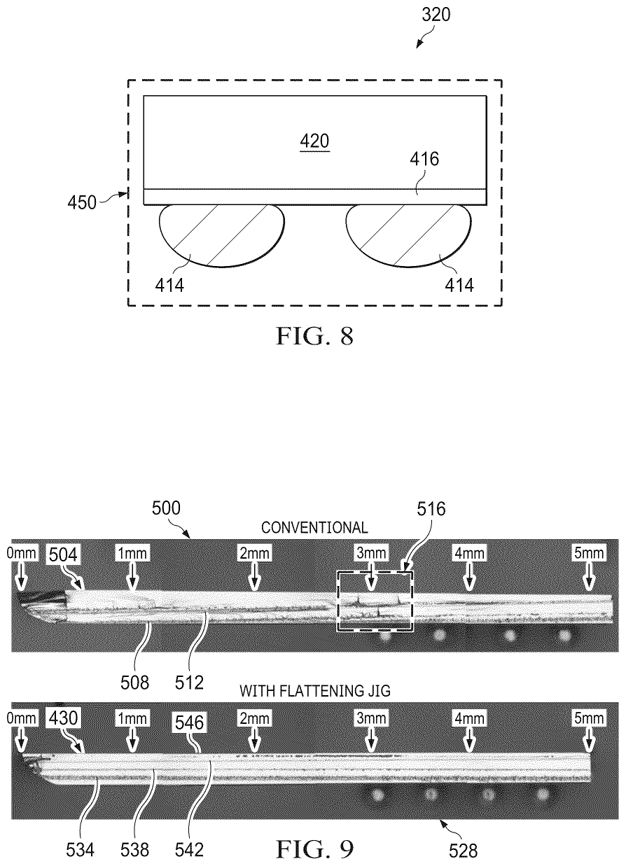

FIG. 9 illustrates photographs of backgrinded wafers, which are wafers (e.g., the wafer 104 of FIG. 1) after backgrinding. FIG. 9 includes a first photograph 500 showing a conventional approach where a flattening jig is not used, such that a first backgrinded wafer 504 has an uneven thickness, as illustrated by uneven cutlines 508 and 512. This uneven thickness is caused by rocking of the first backgrinded wafer 504 during the backgrinding operation because downward pressure is unevenly distributed across the first backgrinded wafer 504. Additionally, due to this uneven downward pressure on the first wafer 504, the first backgrinded wafer 504 includes several cracks 516. These cracks 516 can cause failures in singulated dies, thereby reducing a yield of the wafer 504.

FIG. 9 also includes a second photograph 528 showing an approach where a flattening jig (e.g., the device 100 FIG. 1 that includes the shim 140) is used during the backgrinding of a second backgrinded wafer 530. The flattening jig prevents rocking of the second backgrinded wafer 530 during the backgrinding operation. The second backgrinded wafer has an even thickness, as evidenced by a relatively straight first cut line 534, a second cutline 538 and a third cutline 542. The second backgrinded wafer 530 has a top surface 546 that has a variance (e.g., undulation) of less than 5 μm. Additionally, the second backgrinded wafer 530 has a continuous lattice and does not include cracks (e.g., the several cracks 516 in the first photograph 500). Accordingly, as illustrated, inclusion of the flattening jig improves the results of the backgrinding operation.

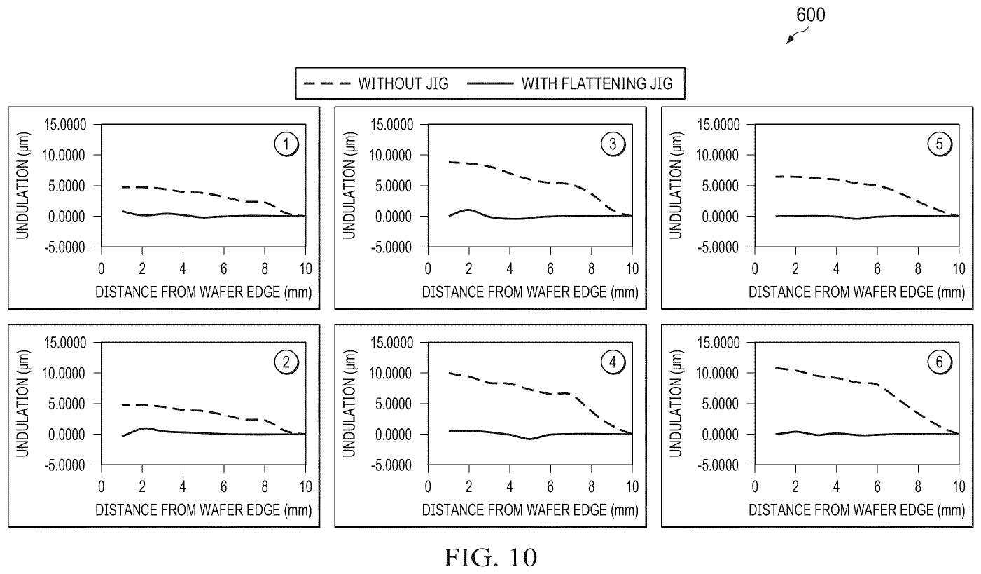

FIG. 10 illustrates a set of graphs 600 (six (6) graphs) that plots an undulation, in μm, of backgrinded wafers (e.g., the wafer 104 of FIG. 1 after backgrinding) as a function of distance, in μm, from an edge of the backgrinded wafer. Each graph of the set of graphs 600 includes a plot for a backgrinded wafer that is backgrinded through a conventional backgrinding operation and without a jig and a plot for a backgrinded wafer that is backgrinded with a flattening jig (e.g., the device 100 with the shim 140 of FIG. 1). As is illustrated, wafers backgrinded with the conventional approach have an undulation (e.g. top side variance) of up to about 10 μm. In contrast, in the examples illustrated, the wafers backgrinded while seated on a flattening jig have an undulation (e.g., top side variance) of about 0.5 μm to about 1 μm.

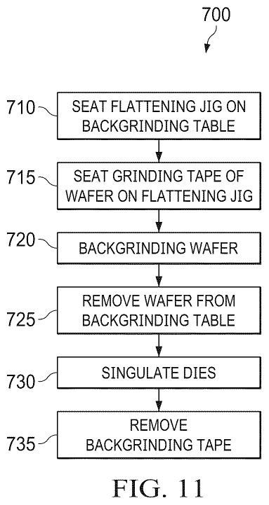

FIG. 11 illustrates a flowchart of an example method 700 for forming IC chips from a wafer, such as the wafer 104 of FIG. 1. Thus, in some examples, the wafer is a WCSP wafer. At 710, a flattening jig (e.g., the device 100) is seated on a grinding table (e.g., the grinding table 108 of FIG. 1). The flattening jig includes a shim (e.g., the shim 140 of FIG. 1). At 715, grinding tape adhered to a first side of a wafer is seated on the flattening jig. The shim has a cross section shaped to mirror a cross section of a step gap formed at an edge of the grinding tape that covers solder balls on the first side of the wafer, such that the shim and the grinding tape form a planer surface on the grinding table. That is, the shim has a gum height to match the step gap of the grinding tape. The step gap has a height of about 40 μm to about 60 μm. In some examples, the grinding tape is placed on a vacuum table (e.g., the vacuum table 152 of FIG. 1) of the grinding table 108.

At 720, a second side of the wafer is backgrinded to form a planer surface on the second side of the wafer. The backgrinding operation includes applying pressure (e.g., a downward force) on the second side of the wafer. The shim of the device is shaped to curtail bending of the wafer about a solder ball of the solder balls that is closest to an edge of the grinding tape. The backgrinding removes a portion of the second side of the wafer to provide a backgrinded wafer, and the backgrinded wafer has a continuous lattice (e.g., no cracks). In some examples, a planer surface on the second side of the wafer formed by the backgrinding has a variance of 5 micrometers or less.

At 725, the wafer is removed from the grinding table. At 730, dies on the wafer are singulated with a saw (e.g., the saw 448 of FIG. 7), such as a laser saw or a plasma saw. At 735, the grinding tape is removed from the singulated dies to expose the solder balls. Removal of the grinding tape enables the resultant singulated dies to be installed (mounted) on a PCB.

In this description, unless otherwise stated, “about” preceding a parameter means being within +/−10 percent of that parameter. Modifications are possible in the described embodiments, and other embodiments are possible, within the scope of the claims.

What is claimed is:

1. A device for a grinding table comprising:
a shim with a cross section shaped to mirror a cross section of a step gap formed at an edge of grinding tape adhered to a first side of a wafer that covers solder balls, such that the shim and the grinding tape form a planer surface on the grinding table for the wafer.

2. The device of claim 1, wherein the device is a flattening jig.

3. The device of claim 1, wherein the step gap has a height measured from a point at a greatest thickness of the grinding tape to a point on a solder ball proximate to the edge of the grinding tape.

4. The device of claim 3, wherein the step gap has a height of about 40 micrometers to about 60 micrometers.

5. The device of claim 1, wherein the planer surface formed by the shim and the grinding tape is configured to be placed on a vacuum table of the grinding table.

6. The device of claim 1, wherein the shim has a circular shape.

7. The device of claim 1, wherein the wafer is a wafer scale chip package (WCSP) wafer.

8. A method for backgrinding a wafer comprising:
seating a device on a grinding table, wherein the device comprises a shim for a wafer;
seating grinding tape adhered to a first side of a wafer on the device, wherein the shim has a cross section shaped to mirror a cross section of a step gap formed at an edge of the grinding tape that covers solder balls on the first side of the wafer, such that the shim and the grinding tape form a planer surface on the grinding table; and
backgrinding a second side of the wafer to form a planer surface on the second side of the wafer.

9. The method of claim 8, further comprising:
removing the wafer from the grinding table; and
singulating dies in the wafer.

10. The method of claim 9, further comprising removing the grinding tape from the singulated dies to expose the solder balls.

11. The method of claim 8, wherein the planer surface on the second side of the wafer has a variance of 5 micrometers or less.

12. The method of claim 8, wherein the device is a flattening jig.

13. The method of claim 8, wherein the step gap has a height measured from a greatest thickness of the grinding tape to a point on a solder ball proximate to the edge of the grinding tape.

14. The method of claim 11, wherein the step gap has a height of about 40 micrometers to about 60 micrometers.

15. The method of claim 8, wherein the planer surface formed by the shim and the grinding tape is configured to be placed on a vacuum table of the grinding table.

16. The method of claim 8, wherein the shim has a circular shape.

17. The method of claim 8, wherein the wafer is a wafer scale chip package (WCSP) wafer.

18. A method for backgrinding a wafer comprising:
seating a device on a grinding table, wherein the device comprises a shim for a wafer;
seating grinding tape adhered to a first side of a wafer on the device, wherein the grinding tape covers solder balls on the first side of the wafer; and
backgrinding a second side of the wafer to form a planer surface on the second side of the wafer, wherein the backgrinding comprises:
applying pressure on the second side of the wafer, wherein the shim of the device is shaped to curtail bending of the wafer about a solder ball of the solder balls that is closest to an edge of the grinding tape; and
removing a portion of the second side of the wafer to provide a backgrinded wafer, and the backgrinded wafer has a continuous lattice.

19. The method of claim 18, wherein the device is a flattening jig.

20. The method of claim 19, wherein the shim of the device has a cross section shaped to mirror a cross section of a step gap formed at the edge of the grinding tape, such that the shim and the grinding tape form a planer surface on the grinding table.
